(19) United States
(12) Patent Application Publication
(10) Pub. No.: US 2022/0352364 A1
(43) Pub. Date: Nov. 3, 2022

(54) TRANSISTOR WITH INCREASED CHANNEL WIDTH AND MANUFACTURING METHOD THEREOF

(71) Applicant: Korea Advanced Institute of Science and Technology, Daejeon (KR)

(72) Inventor: Sanghun JEON, Daejeon (KR)

(73) Assignee: Korea Advanced Institute of Science and Technology, Daejeon (KR)

(21) Appl. No.: 17/732,259

(22) Filed: Apr. 28, 2022

(30) Foreign Application Priority Data
Apr. 30, 2021 (KR) 10-2021-0056170

(51) Int. Cl. H01L 29/78; H01L 29/66; H01L 29/10

(52) U.S. Cl. CPC H01L 29/785; H01L 29/66795; H01L 29/1037

(57) ABSTRACT

Disclosed is a transistor having a structure, in which a channel width is increased, and a manufacturing method thereof. The transistor includes a channel including at least one protrusion part and at least one indentation part, a gate formed to extend in a vertical direction to surround a portion of the channel, a source formed to extend in the vertical direction to surround a portion of the channel while being positioned to be opposite to both sides of the gate, and a drain formed to extend in the vertical direction to surround a portion of the channel while being positioned to be opposite to both sides of the gate.

### CROSS-REFERENCE TO RELATED APPLICATIONS

This application claims priority under 35 U.S.C. § 119 to Korean Patent Application No. 10-2021-0056170 filed on April 30, 2021, in the Korean Intellectual Property Office, the disclosure of which is incorporated by reference herein in its entirety.

### BACKGROUND

Embodiments of the present disclosure described herein relate to a transistor having a structure, in which a channel width is increased, and a manufacturing method thereof.

A conventional non-planar FinFET faces the limitation of scaling. That is, the conventional non-planar FinFET has difficulty in increasing an effective channel width at the same active width.

Technologies such as gate all around FET, nanosheet FET, and the like have been proposed as alternatives. The corresponding technology may secure a larger effective channel width at the same active width but may have an issue that the channel is floating. Accordingly, a change in threshold voltage due to a floating body effect may not be controlled.

Accordingly, it is necessary to propose a device capable of having a large current by having a large channel width in the same area.

### SUMMARY

Embodiments of the present disclosure provide a transistor having a structure, in which a channel width is increased in the same area, and a manufacturing method thereof.

In particular, embodiments of the present disclosure provide a transistor having a structure, in which a channel width is increased by extending a channel in a shape, in which a protrusion part and an indentation part are repeated without floating the channel, to control a change in threshold voltage due to a floating body effect, and a manufacturing method thereof

However, the technical problems to be solved by the present disclosure are not limited to the above problems, and may be variously expanded without departing from the technical spirit and scope of the present disclosure.

According to an embodiment, a transistor includes a channel including at least one protrusion part and at least one indentation part, the at least one protrusion part protruding in a horizontal direction while being formed to extend in a vertical direction on a substrate and the at least one indentation part being recessed in the horizontal direction while being formed to extend in the vertical direction on the substrate, a gate formed to extend in the vertical direction to surround a portion of the channel, a source formed to extend in the vertical direction to surround a portion of the channel while being positioned to be opposite to both sides of the gate, and a drain formed to extend in the vertical direction to surround a portion of the channel while being positioned to be opposite to both sides of the gate.

According to an aspect, the channel includes a structure in which the at least one protrusion part and the at least one indentation part are stacked in the vertical direction and connected to each other.

According to another aspect, the channel is connected to a body of the substrate and formed to extend in the vertical direction, to control a change in a threshold voltage due to a floating body effect.

According to still another aspect, a material for forming the at least one protrusion part is different from a material for forming the at least one indentation part in the channel such that selective etching for the at least one indentation part is possible.

According to yet another aspect, a material for forming the at least one protrusion part is identical to a material for forming the at least one indentation part in the channel.

According to yet another aspect, the gate, the source, and the drain are formed spaced from one another by a specific distance or more without contacting one another.

According to yet another aspect, the transistor further includes a gate dielectric film formed to surround the at least one protrusion part and the at least one indentation part such that the at least one protrusion part and the at least one indentation part included in the channel do not directly contact the gate, the source, and the drain.

According to yet another aspect, the transistor further includes a shallow trench isolation (STI) formed at opposite sides of a body of the substrate on the substrate.

According to an embodiment, a method for manufacturing a transistor includes extending and forming a channel structure in which at least one first material layer and at least one second material layer, which are different from each other, are alternately stacked in a vertical direction on a substrate, forming a trench in the channel structure in the vertical direction, forming at least one connection layer connecting the at least one first material layer by filling the same material as the at least one first material layer in the trench, removing the at least one second material layer from the channel structure, forming at least one protrusion part of a channel with the at least one first material layer protruding in a horizontal direction, and forming at least one indentation part of the channel with the at least one connection layer recessed in the horizontal direction, extending and forming a gate in the vertical direction to surround a portion of the channel, and extending and forming a source and a drain in the vertical direction to surround a portion of the channel while the source and the drain are positioned to be opposite to both sides of the gate.

According to an aspect, the forming of the at least one protrusion part of the channel and the forming of the at least one indentation part of the channel include extending and forming the channel to include a structure in which the at least one protrusion part and the at least one indentation part are stacked in the vertical direction and connected to each other.

According to another aspect, the method for manufacturing the transistor further includes forming a gate dielectric film to surround the at least one protrusion part and the at least one indentation part such that the at least one protrusion part and the at least one indentation part included in the channel do not directly contact the gate, the source, and the drain after the forming of the at least one protrusion part of the channel and the forming of the at least one indentation part of the channel.

According to still another aspect, the method for manufacturing the transistor further includes forming STI at both side of a location, at which the channel structure is to be extended and formed, before the extending and forming of the channel structure.

According to an embodiment, a method for manufacturing a transistor includes extending and forming a channel structure in which at least one first material layer and at least one second material layer, which are different from each other, are alternately stacked in a vertical direction on a substrate, removing a portion of the at least one second material layer from the channel structure, forming at least one protrusion part of a channel with the at least one first material layer protruding in a horizontal direction, and forming at least one indentation part of the channel with the at least one second material layer recessed in the horizontal direction, extending and forming a gate in the vertical direction to surround a portion of the channel, and extending and forming a source and a drain in the vertical direction to surround a portion of the channel while the source and the drain are positioned to be opposite to both sides of the gate.

According to an aspect, the forming of the at least one protrusion part of the channel and the forming of the at least one indentation part of the channel include extending and forming the channel to include a structure in which the at least one protrusion part and the at least one indentation part are stacked in the vertical direction and connected to each other.

According to another aspect, the method for manufacturing the transistor further includes forming a gate dielectric film to surround the at least one protrusion part and the at least one indentation part such that the at least one protrusion part and the at least one indentation part included in the channel do not directly contact the gate, the source, and the drain after the forming of the at least one protrusion part of the channel and the forming of the at least one indentation part of the channel.

According to still another aspect, the method for manufacturing the transistor further includes forming STI at both side of a location, at which the channel structure is to be extended and formed, before the extending and forming of the channel structure.

### BRIEF DESCRIPTION OF THE FIGURES

The above and other objects and features of the present disclosure will become apparent by describing in detail embodiments thereof with reference to the accompanying drawings.

FIGS. 1A and 1B are perspective views illustrating a transistor, according to an embodiment.

FIGS. 2A and 2B are diagrams for describing the superiority of the transistor shown in FIGS. 1A to 1B.

FIG. 3 is a flowchart illustrating a transistor manufacturing method for manufacturing a transistor shown in FIGS. 1A and 1B, according to an embodiment.

FIGS. 4A to 4I are cross-sectional views for describing a method of manufacturing the transistor shown in FIG. 3.

FIG. 5 is a flowchart illustrating a transistor manufacturing method for manufacturing a transistor shown in FIGS. 1A and 1B, according to another embodiment.

FIGS. 6A to 6F are cross-sectional views for describing a method of manufacturing the transistor shown in FIG. 5.

### DETAILED DESCRIPTION

Hereinafter, a description will be given in detail for embodiments of the present disclosure with reference to the following drawings. However, the present disclosure are not limited or restricted by the embodiments. Further, the same reference signs/numerals in the drawings denote the same members.

Furthermore, the terminologies used herein are used to properly express the embodiments of the present disclosure, and may be changed according to the intentions of a viewer or the manager or the custom in the field to which the present disclosure pertains. Therefore, definition of the terminologies should be made according to the overall disclosure set forth herein. For example, in the specification, the singular forms include plural forms unless particularly mentioned. Furthermore, the terminologies “comprises” and/or “comprising” used herein does not exclude presence or addition of one or more other components, steps, operations, and/or elements in addition to the aforementioned components, steps, operations, and/or elements.

Moreover, it should be understood that various embodiments of the present disclosure are not necessarily mutually exclusive although being different from each other. For example, specific shapes, structures, and characteristics described herein may be implemented in other embodiments without departing from the spirit and scope of the present disclosure in relation to one embodiment. Besides, it should be understood that the location, arrangement, or configuration of individual components in each of presented categories of an embodiment may be changed without departing from the spirit and scope of the present disclosure.

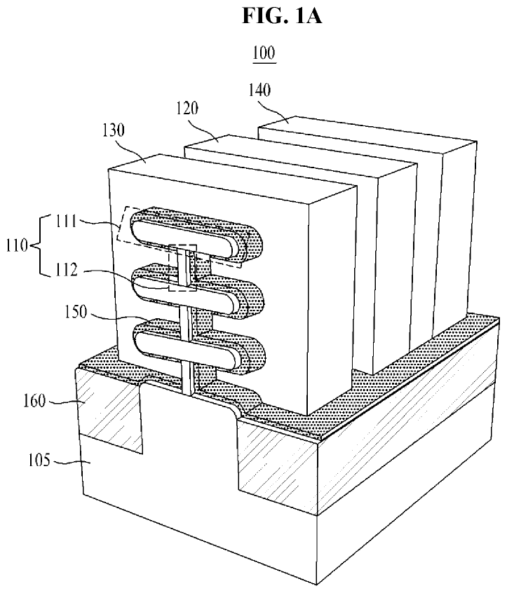

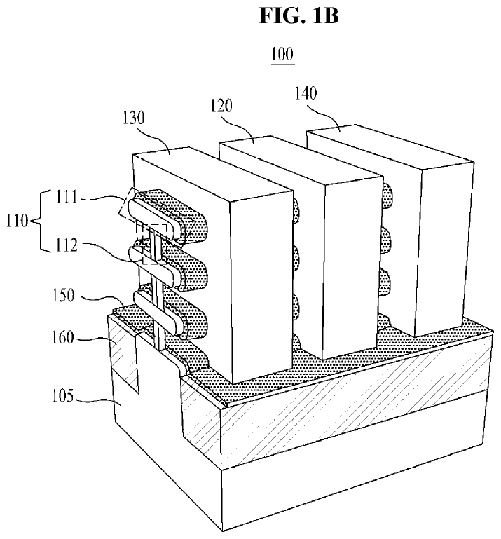

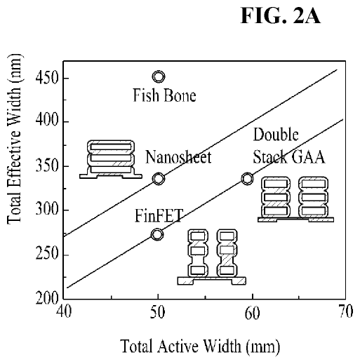

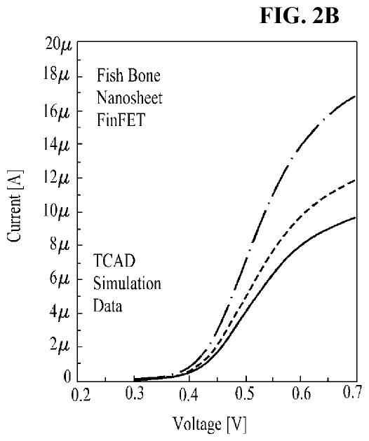

FIGS. 1A and 1B are perspective views illustrating a transistor, according to an embodiment. FIGS. 2A and 2B are diagrams for describing the superiority of the transistor shown in FIGS. 1A to 1B.

Referring to FIGS. 1A and 1B, a transistor 100 according to an embodiment may include a channel 110, a gate 120, a source 130, and a drain 140.

All the components are formed on a substrate 105. Here, the substrate 105 may be formed of a silicon (Si)-based material such that the channel 110 is formed through epitaxial growth from the substrate 105 in a manufacturing method to be described later.

The channel 110 may include at least one protrusion part 111 and at least one indentation part 112. The at least one protrusion part 111 protrudes in a horizontal direction while extending in a vertical direction on the substrate 105, and the at least one indentation part 112 is recessed in the horizontal direction while extending in the vertical direction on the substrate 105. That is, the channel 110 may have a structure in which the at least one protrusion part 111 and the at least one indentation part 112 are vertically stacked and connected (the channel 110 has a shape similar to a fish bone when viewed from the side, and thus may be referred to as a “fish bone structure”).

As such, the channel 110 may include the at least one protrusion part 111 protruding in the horizontal direction. As shown in FIG. 2A, the channel 110 has a structure with an increased channel width compared to the conventional FinFET, thereby increasing an on-current of a transistor as shown in FIG. 2B.

Moreover, the channel 110 has a structure with an increased channel width. Furthermore, the channel 110 may be connected to a body of the substrate 105 and may extend in a vertical direction. Accordingly, a change in a threshold voltage due to floating body effect may be controlled.

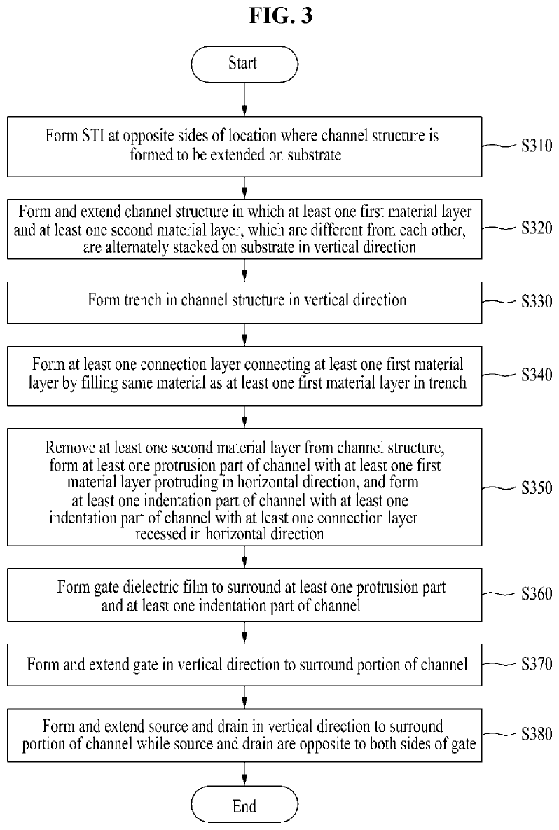

In this case, in the channel 110, a material for forming the at least one protrusion part 111 and a material for forming the at least one indentation part 112 may be the same as each other as shown in the drawings. For example, both the at least one protrusion part 111 and the at least one indentation part 112 may be formed of silicon (Si). In this case, a method of manufacturing the transistor 100 will be described with reference to FIG. 3 below.

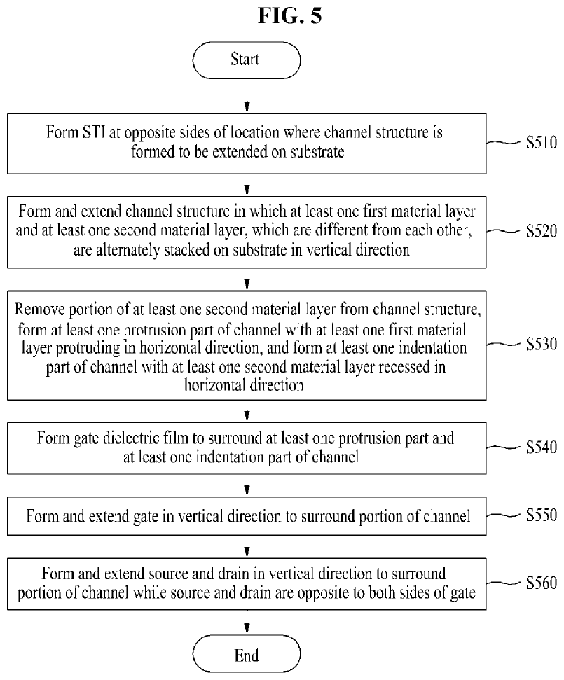

On the other hand, in the channel 110, a material for forming the at least one protrusion part 111 and a material forming the at least one indentation part 112 may be different from each other such that the at least one indentation part 112 is selectively etched in a manufacturing method to be described later unlike the drawings. For example, the at least one protrusion part 111 may be formed of silicon (Si), and the at least one indentation part 112 may be formed of germanium (Ge) or silicon germanium (SiGe). In this case, a method of manufacturing the transistor 100 will be described with reference to FIG. 5 below.

The gate 120 may be formed to extend in a vertical direction such that the gate 120 surrounds a portion of the channel 110. The material forming the gate 120 may include at least one of polysilicon, polysilicon doped with n-type impurities of high concentration, polysilicon doped with p-type impurities of high concentration, tungsten (W), titanium nitride (TiN), tantalum nitride (TaN), tungsten nitride film (WN), aluminum (Al), molybdenum (Mo), chromium (Cr), platinum (Pt), or titanium (Ti).

While being disposed to be opposite to both sides of the gate 120, the source 130 and the drain 140 may be formed to extend in a vertical direction such that the source 130 and the drain 140 surround a portion of the channel 110. Here, the source 130 and the drain 140 may be formed by doping impurities into the same material (e.g., silicon (Si)) as the substrate 105 through ion implantation.

As such, the gate 120, the source 130, and the drain 140 may be formed spaced from each other by a specific distance or more without contacting one another.

Besides, the transistor 100 may further include a gate dielectric film 150 formed to surround the outside of the channel 110 sure that the channel 110 does not directly contact the gate 120, the source 130 and the drain 140. That is, the gate dielectric film 150 may be formed to surround the at least one protrusion part 111 and the at least one indentation part 112 of the channel 110 such that the at least one protrusion part 111 and the at least one indentation part 112 do not directly contact the gate 120, the source 130, and the drain 140. The gate dielectric film 150 may be formed of at least one material of a silicon oxide film, a nitride film, an aluminum oxide film, a hafnium oxide film, a silicon-doped hafnium oxide (Si:HfO₂) film, an aluminum-doped hafnium oxide (Al:HfO₂) film, a lanthanum-doped hafnium oxide (La:HfO₂) film, a yttrium-doped hafnium oxide (Y:HfO₂) film, a strontium-doped hafnium oxide (Sr:HfO₂) film, a hafnium oxynitride film, a zinc oxide film, a lanthanum oxide film, and a hafnium silicon oxide film, a hafnium zirconium oxide film, a barium titanate (BaTiO₃) film, a lead titanate (PbTiO₃) film, a calcium titanate (CaTiO₃) film, a potassium niobate (KNbO₃) film, a lead zirconate titanate (PZT) film, a SrBi2Ta2O9 film, or a bismuth ferrite (BFO) film.

In addition, the transistor 100 may further include a shallow trench isolation (STI) 160 formed on opposite sides of the body of the substrate 105 on the substrate 105. Accordingly, the channel 110, the gate 120, the source 130, and the drain 140 of the transistor 100 may be separated from neighboring transistors (not shown).

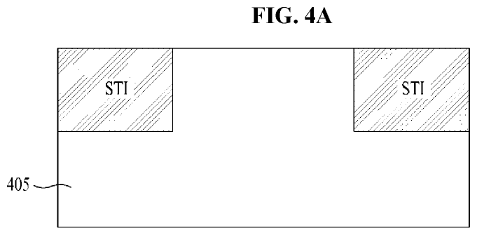

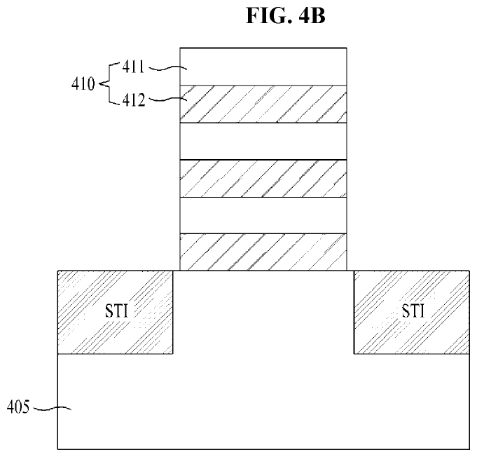

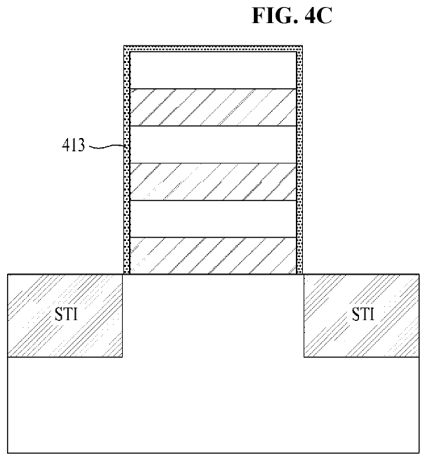

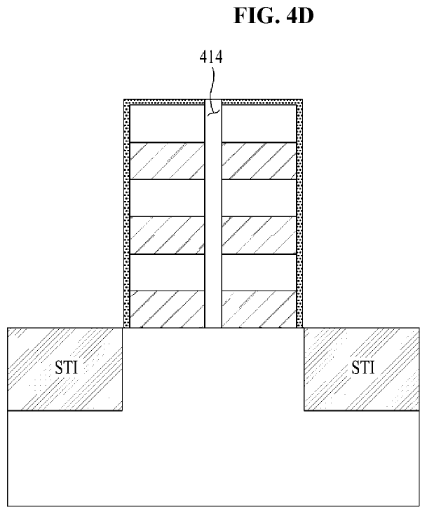

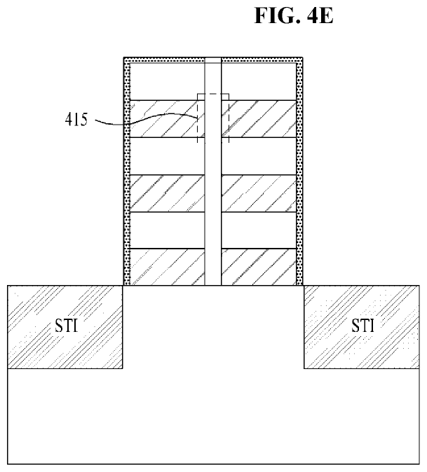

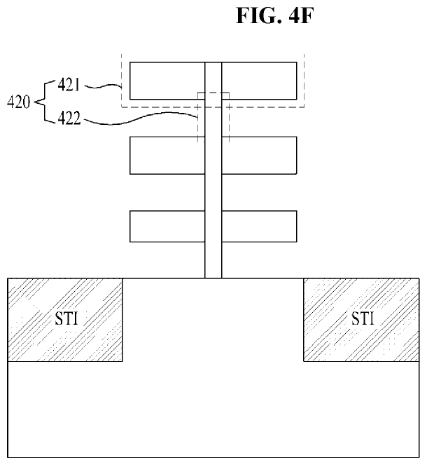

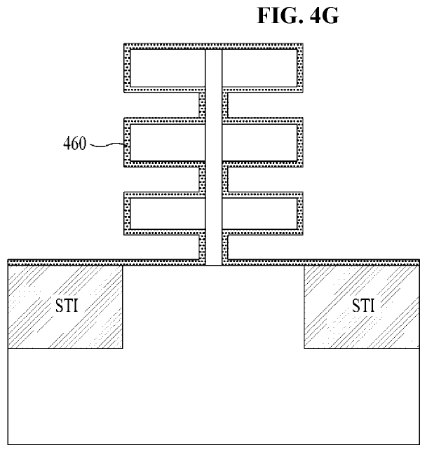

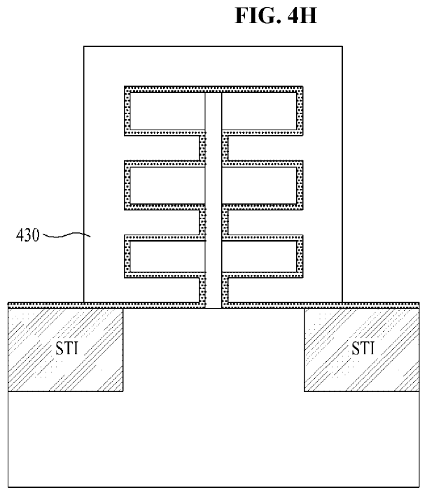

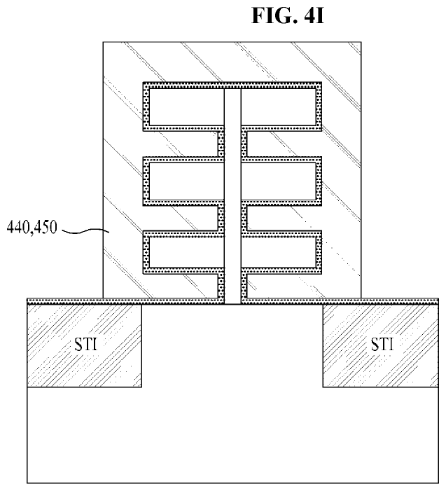

FIG. 3 is a flowchart illustrating a transistor manufacturing method for manufacturing a transistor shown in FIGS. 1A and 1B, according to an embodiment. FIGS. 4A to 41 are cross-sectional views for describing a method of manufacturing the transistor shown in FIG. 3.

Hereinafter, a manufacturing method may be performed by an automated and mechanized manufacturing system. The transistor 100 described with reference to FIGS. 1A and 1B may be obtained by performing the manufacturing method.

In step S310, as shown in FIG. 4A, the manufacturing system may form STI at opposite sides of a location where a channel structure 410 is to be extended and formed on a substrate 405, through step S320 to be described later.

Here, the substrate 405 may be formed of a silicon (Si)-based material such that the channel structure 410 is capable of being formed through epitaxial growth through step S320 to be described later.

Then, in step S320, as shown in FIG. 4B, the manufacturing system may extend and form the channel structure 410 in which at least one first material layer 411 and at least one second material layer 412, which are different from each other, are alternately stacked on the substrate 405 in a vertical direction. At this time, the manufacturing system may use the epitaxial growth in extending and forming the channel structure 410.

For example, the manufacturing system may form the at least one first material layer 411 with silicon (Si) and may form the at least one second material layer 412 with germanium (Ge).

Although not shown as a separate step, after step 320, the manufacturing system may form an oxide film 413 to surround the channel structure 410 as shown in FIG. 4C. In some cases, the corresponding process may be omitted.

Next, in step S330, as shown in FIG. 4D, the manufacturing system may form a trench 414 in the channel structure 410 in a vertical direction.

Next, in step S340, as shown in FIG. 4E, the manufacturing system may form at least one connection layer 415 connecting the at least one first material layer 411 by filling the same material as the at least one first material layer 411 in the trench 414. The manufacturing system may use epitaxial growth in forming the at least one connection layer 415.

For example, the manufacturing system may form the at least one connection layer 415 with silicon (Si), which is the same material as the at least one first material layer 411.

Next, in step S350, as shown in FIG. 4F, the manufacturing system may remove the at least one second material layer 412 from the channel structure 410, may form the at least one protrusion part 421 of the channel 420 with the at least one first material layer 411 protruding in a horizontal direction, and may form the at least one indentation part 422 of the channel 420 with the at least one connection layer 415 recessed in the horizontal direction. That is, the manufacturing system may extend and form the channel 420 to have a fish bone structure in which the at least one protrusion part 421 and the at least one indentation part 422 are vertically stacked and connected to each other.

At this time, the manufacturing system may remove only the at least one second material layer 412 through selective etching to the at least one second material layer 412.

Next, in step S360, as shown in FIG. 4G, the manufacturing system may form a gate dielectric film 460 to surround the at least one protrusion part 421 and the at least one indentation part 422 of the channel 420 such that the at least one protrusion part 421 and the at least one indentation part 422 of the channel 420 do not directly contact a gate 430, a source 440, and a drain 450. The gate dielectric film 460 may be formed of at least one material of a silicon oxide film, a nitride film, an aluminum oxide film, a hafnium oxide film, a silicon-doped hafnium oxide (Si:HfO₂) film, an aluminum-doped hafnium oxide (Al:HfO₂) film, a lanthanum-doped hafnium oxide (La:HfO₂) film, a yttrium-doped hafnium oxide (Y:HfO₂) film, a strontium-doped hafnium oxide (Sr:HfO₂) film, a hafnium oxynitride film, a zinc oxide film, a lanthanum oxide film, and a hafnium silicon oxide film, a hafnium zirconium oxide film, a barium titanate (BaTiO₃) film, a lead titanate (PbTiO₃) film, a calcium titanate (CaTiO₃) film, a potassium niobate (KNbO₃) film, a lead zirconate titanate (PZT) film, a SrBi2Ta2O9 film, or a bismuth ferrite (BFO) film.

Next, in step 5370, as shown in FIG. 4H, the manufacturing system may extend and form the gate 430 in a vertical direction to surround a portion of the channel 420. The gate 430 may be formed of at least one of polysilicon, polysilicon doped with n-type impurities of high concentration, polysilicon doped with p-type impurities of high concentration, tungsten (W), titanium nitride (TiN), tantalum nitride (TaN), tungsten nitride film (WN), aluminum (Al), molybdenum (Mo), chromium (Cr), platinum (Pt), or titanium (Ti).

Next, in step 5380, as shown in FIG. 41, the manufacturing system may extend and form the source 440 and the drain 450 in a vertical direction to surround a portion of the channel 420 while the source 440 and the drain 450 are opposite to both sides of the gate 430. The source 440 and the drain 450 may be formed by doping impurities into the same material (e.g., silicon (Si)) as the substrate 405 through ion implantation.

At this time, the gate 430, the source 440, and the drain 450 formed through step S370 to step S380 may be spaced from one another by a specific distance or more without contacting one another.

The transistor 400 manufactured in this way has a structure in which a channel width is increased compared to the conventional FinFET, thereby increasing an on-current of a transistor. Furthermore, the channel 420 may be connected to a body of the substrate 405 and may extend in a vertical direction. Accordingly, a change in a threshold voltage due to floating body effect may be controlled.

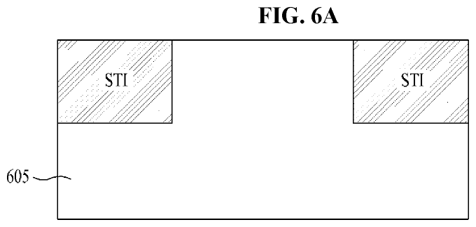

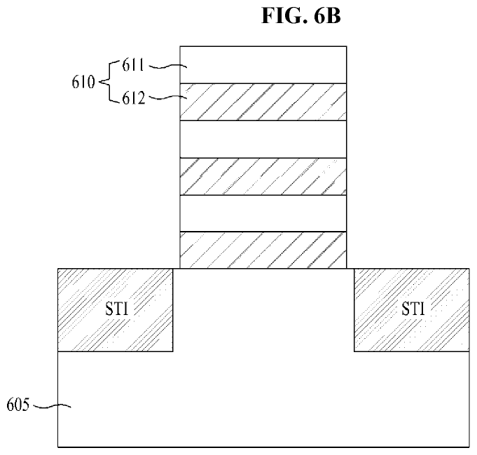

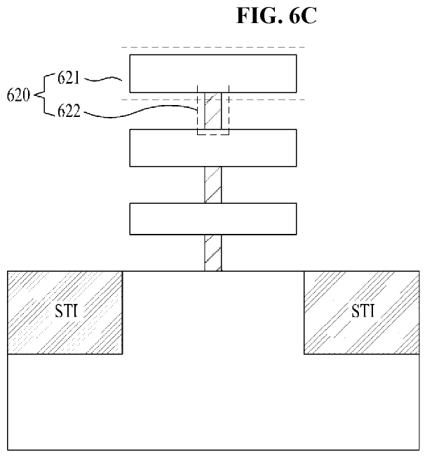

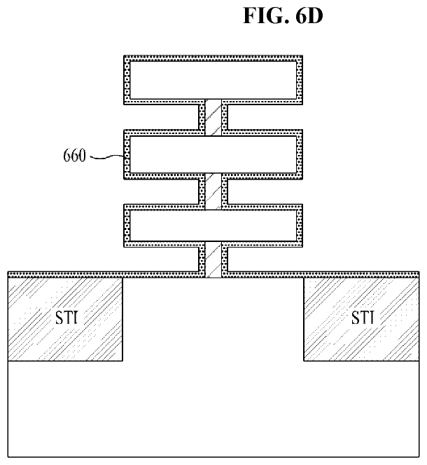

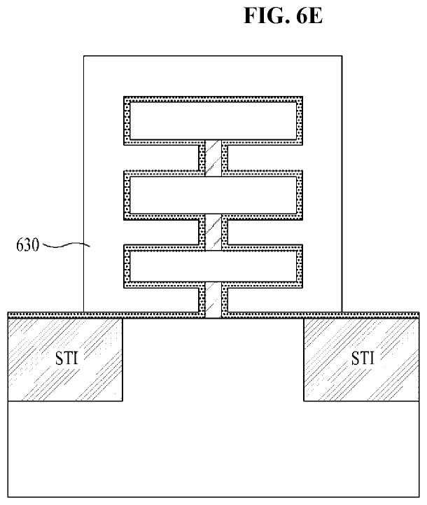

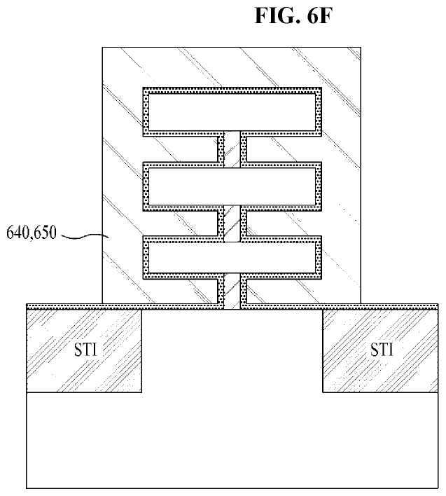

FIG. 5 is a flowchart illustrating a transistor manufacturing method for manufacturing a transistor shown in FIGS. 1A and 1B, according to another embodiment. FIGS. 6A to 6F are cross-sectional views for describing a method of manufacturing the transistor shown in FIG. 5.

Hereinafter, a manufacturing method may be performed by an automated and mechanized manufacturing system. A transistor obtained by performing the manufacturing method may have a structure the same as the transistor 100 described with reference to FIGS. 1A and 1B. However, the transistor is different from the transistor 100 shown in FIGS. 1A and 1B in that at least one indentation part and at least one protrusion part are formed of different materials from each other.

In step S510, as shown in FIG. 6A, the manufacturing system may form STI at opposite sides of a location where a channel structure 610 is to be extended and formed on a substrate 605, through step S620 to be described later.

Here, the substrate 605 may be formed of a silicon (Si)-based material such that the channel structure 610 is capable of being formed through epitaxial growth through step S520 to be described later.

Then, in step S520, as shown in FIG. 6B, the manufacturing system may extend and form the channel structure 610 in which at least one first material layer 611 and at least one second material layer 612, which are different from each other, are alternately stacked on the substrate 605 in a vertical direction. At this time, the manufacturing system may use the epitaxial growth in extending and forming the channel structure 610.

For example, the manufacturing system may form the at least one first material layer 611 with silicon (Si) and may form the at least one second material layer 612 with germanium (Ge) or silicon germanium (SiGe).

Next, in step S530, as shown in FIG. 6C, the manufacturing system may remove a portion of the at least one second material layer 612 from the channel structure 610, may form the at least one protrusion part 621 of the channel 620 with the at least one first material layer 611 protruding in a horizontal direction, and may form the at least one indentation part 622 of the channel 620 with the at least one second material layer 612 recessed in the horizontal direction. That is, the manufacturing system may extend and form the channel 620 to have a fish bone structure in which the at least one protrusion part 621 and the at least one indentation part 622 are vertically stacked and connected to each other.

At this time, the manufacturing system may remove a portion of the at least one second material layer 612 and may leave the other thereof by adjusting the degree of selective etching for the at least one second material layer 612.

Next, in step S540, as shown in FIG. 6D, the manufacturing system may form a gate dielectric film 660 to surround the at least one protrusion part 621 and the at least one indentation part 622 of the channel 620 such that the at least one protrusion part 621 and the at least one indentation part 622 of the channel 620 do not directly contact a gate 630, a source 640, and a drain 650. The gate dielectric film 660 may be formed of at least one material of a silicon oxide film, a nitride film, an aluminum oxide film, a hafnium oxide film, a silicon-doped hafnium oxide (Si:HfO₂) film, an aluminum-doped hafnium oxide (Al:HfO₂) film, a lanthanum-doped hafnium oxide (La:HfO₂) film, a yttrium-doped hafnium oxide (Y:HfO₂) film, a strontium-doped hafnium oxide (Sr:HfO₂) film, a hafnium oxynitride film, a zinc oxide film, a lanthanum oxide film, and a hafnium silicon oxide film, a hafnium zirconium oxide film, a barium titanate (BaTiO₃) film, a lead titanate (PbTiO₃) film, a calcium titanate (CaTiO₃) film, a potassium niobate (KNbO₃) film, a lead zirconate titanate (PZT) film, a SrBi2Ta2O9 film, or a bismuth ferrite (BFO) film.

Next, in step S550, as shown in FIG. 6E, the manufacturing system may extend and form the gate 630 in a vertical direction to surround a portion of the channel 620. The gate 630 may be formed of at least one of polysilicon, polysilicon doped with n-type impurities of high concentration, polysilicon doped with p-type impurities of high concentration, tungsten (W), titanium nitride (TiN), tantalum nitride (TaN), tungsten nitride film (WN), aluminum (Al), molybdenum (Mo), chromium (Cr), platinum (Pt), or titanium (Ti).

Next, in step 5560, as shown in FIG. 6F, the manufacturing system may extend and form the source 640 and the drain 650 in a vertical direction to surround a portion of the channel 620 while the source 440 and the drain 450 are opposite to both sides of the gate 630. The source 640 and the drain 650 may be formed by doping impurities into the same material (e.g., silicon (Si)) as the substrate 605 through ion implantation.

At this time, the gate 630, the source 640, and the drain 650 formed through step S550 to step S560 may be spaced from one another by a specific distance or more without contacting one another.

The transistor 600 manufactured in this way has a structure in which a channel width is increased compared to the conventional FinFET, thereby increasing an on-current of a transistor. Furthermore, the channel 620 may be connected to a body of the substrate 605 and may extend in a vertical direction. Accordingly, a change in a threshold voltage due to floating body effect may be controlled.

While a few embodiments have been shown and described with reference to the accompanying drawings, it will be apparent to those skilled in the art that various modifications and variations can be made from the foregoing descriptions. For example, adequate effects may be achieved even if the foregoing processes and methods are carried out in different order than described above, and/or the aforementioned elements, such as systems, structures, devices, or circuits, are combined or coupled in different forms and modes than as described above or be substituted or switched with other components or equivalents.

Therefore, other implements, other embodiments, and equivalents to claims are within the scope of the following claims.

Embodiments may provide a transistor having a structure, in which a channel width is increased in the same area, and a manufacturing method thereof.

In particular, embodiment may provide a transistor having a structure in which a channel width is increased by forming a channel to extend in a shape, in which a protrusion part and an indentation part are repeated without floating the channel, and a method for manufacturing the same, thereby controlling a change in a threshold voltage due to a floating body effect.

However, the effects of the present disclosure are not limited to the effects, and may be variously expanded without departing from the spirit and scope of the present disclosure.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A transistor comprising:
a channel including at least one protrusion part and at least one indentation part, wherein the at least one protrusion part protrudes in a horizontal direction while being formed to extend in a vertical direction on a substrate and the at least one indentation part is recessed in the horizontal direction while being formed to extend in the vertical direction on the substrate;
a gate formed to extend in the vertical direction to surround a portion of the channel;
a source formed to extend in the vertical direction to surround a portion of the channel while being positioned to be opposite to both sides of the gate; and
a drain formed to extend in the vertical direction to surround a portion of the channel while being positioned to be opposite to both sides of the gate.

2. The transistor of claim 1, wherein the channel includes a structure in which the at least one protrusion part and the at least one indentation part are stacked in the vertical direction and connected to each other.

3. The transistor of claim 1, wherein the channel is connected to a body of the substrate and formed to extend in the vertical direction, to control a change in a threshold voltage due to a floating body effect.

4. The transistor of claim 1, wherein a material for forming the at least one protrusion part is different from a material for forming the at least one indentation part in the channel such that selective etching for the at least one indentation part is possible.

5. The transistor of claim 1, wherein a material for forming the at least one protrusion part is identical to a material for forming the at least one indentation part in the channel.

6. The transistor of claim 1, wherein the gate, the source, and the drain are formed spaced from one another by a specific distance or more without contacting one another.

7. The transistor of claim 1, further comprising:
a gate dielectric film formed to surround the at least one protrusion part and the at least one indentation part such that the at least one protrusion part and the at least one indentation part included in the channel do not directly contact the gate, the source, and the drain.

8. The transistor of claim 1, further comprising:
a shallow trench isolation (STI) formed at opposite sides of a body of the substrate on the substrate.

9. A method for manufacturing a transistor, the method comprising:
extending and forming a channel structure in which at least one first material layer and at least one second material layer, which are different from each other, are alternately stacked in a vertical direction on a substrate;
forming a trench in the channel structure in the vertical direction;
forming at least one connection layer connecting the at least one first material layer by filling the same material as the at least one first material layer in the trench;
removing the at least one second material layer from the channel structure, forming at least one protrusion part of a channel with the at least one first material layer protruding in a horizontal direction, and
forming at least one indentation part of the channel with the at least one connection layer recessed in the horizontal direction;
extending and forming a gate in the vertical direction to surround a portion of the channel; and
extending and forming a source and a drain in the vertical direction to surround a portion of the channel while the source and the drain are positioned to be opposite to both sides of the gate.

10. The method of claim 9, wherein the forming of the at least one protrusion part of the channel and the forming of the at least one indentation part of the channel include:
extending and forming the channel to include a structure in which the at least one protrusion part and the at least one indentation part are stacked in the vertical direction and connected to each other.

11. The method of claim 9, further comprising:
after the forming of the at least one protrusion part of the channel and the forming of the at least one indentation part of the channel, forming a gate dielectric film to surround the at least one protrusion part and the at least one indentation part such that the at least one protrusion part and the at least one indentation part included in the channel do not directly contact the gate, the source, and the drain.

12. The method of claim 9, further comprising:
before the extending and forming of the channel structure, forming STI at both side of a location at which the channel structure is to be extended and formed.

13. A method for manufacturing a transistor, the method comprising:
extending and forming a channel structure in which at least one first material layer and at least one second material layer, which are different from each other, are alternately stacked in a vertical direction on a substrate;
removing a portion of the at least one second material layer from the channel structure, forming at least one protrusion part of a channel with the at least one first material layer protruding in a horizontal direction, and forming at least one indentation part of the channel with the at least one second material layer recessed in the horizontal direction;
extending and forming a gate in the vertical direction to surround a portion of the channel; and
extending and forming a source and a drain in the vertical direction to surround a portion of the channel while the source and the drain are positioned to be opposite to both sides of the gate.

14. The method of claim 13, wherein the forming of the at least one protrusion part of the channel and the forming of the at least one indentation part of the channel include:
extending and forming the channel to include a structure in which the at least one protrusion part and the at least one indentation part are stacked in the vertical direction and connected to each other.

15. The method of claim 13, further comprising:
after the forming of the at least one protrusion part of the channel and the forming of the at least one indentation part of the channel, forming a gate dielectric film to surround the at least one protrusion part and the at least one indentation part such that the at least one protrusion part and the at least one indentation part included in the channel do not directly contact the gate, the source, and the drain.

16. The method of claim 13, further comprising:
before the extending and forming of the channel structure, forming STI at both side of a location at which the channel structure is to be extended and formed.
